(19) United States
(12) Patent Application Publication
(10) Pub. No.: US 2025/0336843 A1
(43) Pub. Date: Oct. 30, 2025

(54) ALIGNMENT MARK, ALIGNMENT MARK PAIR, SUBSTRATE, AND MANUFACTURING METHOD OF SEMICONDUCTOR DEVICE

(71) Applicant: CANON KABUSHIKI KAISHA, Tokyo (JP)

(72) Inventors: Ryo NAKAYAMA, Tochigi (JP); Takahiro MATSUMOTO, Tochigi (JP); Takafumi MIYAHARU, Tochigi (JP)

(21) Appl. No.: 19/191,027

(22) Filed: Apr. 28, 2025

(30) Foreign Application Priority Data
Apr. 30, 2024 (JP) 2024-074039

(51) Int. Cl. H01L 23/544; H01L 21/68

(52) U.S. Cl. CPC H01L 23/544; H01L 21/682; H01L 2223/54426

(57) ABSTRACT

An alignment mark formed by a plurality of first components each having a rectangular shape and a plurality of second components each having a rectangular shape are arrayed in a checkerboard pattern. Each first component is formed from a flat region. Each second component is formed from a line-and-space pattern having a periodicity in a first direction. A length of the first component in the first direction is an odd multiple of a half pitch of the line-and-space pattern. The line-and-space pattern of each second component is line-symmetric with respect to a straight line passing through a center of the second component in parallel to a second direction orthogonal to the first direction.

### BACKGROUND OF THE INVENTION

### Field of the Invention

The present invention relates to an alignment mark, an alignment mark pair, a substrate, and a manufacturing method of a semiconductor device.

### Description of the Related Art

Japanese Patent Laid-Open No. 2023-044418 describes a mark including an X mark and a Y mark. The X mark is formed from a line-and-space (L/S) pattern extending in a direction along the X direction, and the Y mark is formed from an L/S pattern extending in a direction along the Y direction.

When an alignment mark is arranged on a substrate with a line-and-space pattern uniformly formed thereon, depending on the relative position between the line-and-space pattern and the alignment mark, a distortion or the like can occur in a measurement signal obtained from the alignment mark.

### SUMMARY OF THE INVENTION

The present invention provides a technique concerning an alignment mark suitable for arranging on a substrate with a line-and-space pattern uniformly formed thereon.

One of aspects of the present invention provides an alignment mark in which a plurality of first components each having a rectangular shape and a plurality of second components each having a rectangular shape are arrayed in a checkerboard pattern, wherein each first component is formed from a flat region, each second component is formed from a line-and-space pattern having a periodicity in a first direction, a length of the first component in the first direction is an odd multiple of a half pitch of the line-and-space pattern, and the line-and-space pattern of each second component is line-symmetric with respect to a straight line passing through a center of the second component in parallel to a second direction orthogonal to the first direction.

Further features of the present invention will become apparent from the following description of exemplary embodiments with reference to the attached drawings.

### BRIEF DESCRIPTION OF THE DRAWINGS

FIG. 1 is a view showing the arrangement of an imprint apparatus according to the first embodiment;

FIGS. 2A and 2B are views exemplarily showing the arrangement of a detection apparatus according to the first embodiment;

FIG. 3 is a view exemplarily showing the arrangement of an alignment mark according to the first embodiment;

FIG. 4 is a view showing the first arrangement example of the alignment mark according to the first embodiment;

FIG. 5 is a view showing the second arrangement example of the alignment mark according to the first embodiment;

FIG. 6 is a view schematically showing the arrangement of a detection apparatus according to the second embodiment;

FIG. 7 is a view exemplarily showing the arrangement of an alignment mark according to the second embodiment; and

FIG. 8 is a view exemplarily showing a manufacturing method of an alignment mark or a semiconductor device.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

An alignment mark according to the embodiment can be used to detect a position deviation between a substrate and an original by a detection apparatus. The detection apparatus can be incorporated in, for example, a lithography apparatus such as an imprint apparatus or an exposure apparatus, or an inspection apparatus such as an overlay inspection apparatus.

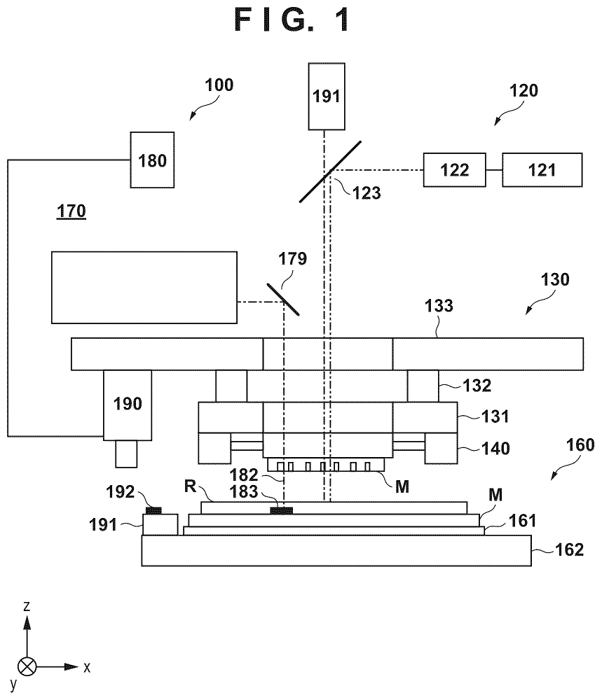

FIG. 1 shows an example of the arrangement of an imprint apparatus 100 as a lithography apparatus according to the first embodiment. The imprint apparatus 100 is an apparatus that brings a mold and an imprint material arranged on a substrate into contact with each other and then cures the imprint material by applying curing energy, thereby forming a pattern on the substrate to which the pattern of the mold is transferred.

As an imprint material, a curable composition (to be also referred to as a resin in an uncured-state) that is cured by receiving curing energy is used. Examples of the curing energy are an electromagnetic wave, heat, and the like. The electromagnetic wave can be, for example, light selected from the wavelength range of 10 nm (inclusive) to 1 mm (inclusive), for example, infrared light, a visible light beam, or ultraviolet light. The curable composition can be a composition cured by light irradiation or heating. Among compositions, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The imprint material can be arranged, by an imprint material supply apparatus (not shown), on the substrate in the form of droplets or in the form of an island or film formed by connecting a plurality of droplets. The viscosity (the viscosity at 25° C.) of the imprint material can be, for example, 1 mPa·s (inclusive) to 100 mPa·s (inclusive). As the material of the substrate, for example, glass, a ceramic, a metal, a semiconductor, a resin, or the like can be used. A member made of a material different from the substrate may be provided on the surface of the substrate, as needed. The substrate is, for example, a silicon wafer, a compound semiconductor wafer, or silica glass.

In the specification and the drawings, directions will be indicated by a xyz coordinate system in which the horizontal surface is set as the x-y plane. A substrate W is placed on a substrate stage 162 such that the surface of the substrate W is parallel to the horizontal surface (x-y plane). Therefore, in the following description, the directions orthogonal to each other in a plane along the surface of the substrate W are the x-axis and the y-axis, and the direction perpendicular to the x-axis and the y-axis is the z-axis. Further, in the following description, directions parallel to the x-axis, the y-axis, and the z-axis of the xyz coordinate system are referred to as the x direction, the y direction, and the z direction, respectively, and a rotational direction around the x-axis, a rotational direction around the y-axis, and a rotational direction around the z-axis are referred to as the Ox direction, the Oy direction, and the Oz direction, respectively.

In an example, the imprint apparatus 100 cures an imprint material by irradiation of UV light (ultraviolet light) serving as curing energy. However, the imprint apparatus 100 may be an imprint apparatus that cures the imprint material by irradiation of light of another wavelength range, or may be an imprint apparatus that cures the imprint material by another energy (for example, heat).

The imprint apparatus 100 can be configured to form a pattern in each of a plurality of shot regions on the substrate W by repeating an imprint process. The imprint process is a process of forming a pattern in one shot region on the substrate W by curing an imprint material R in a state in which the pattern of a mold M is in contact with the imprint material R.

The imprint apparatus 100 can include a curing unit 120, a mold operation mechanism 130, a mold shape correction mechanism 140, a substrate driving unit 160, a detection apparatus 170, a supply unit 190, an observation scope 193, and a control unit 180. Although not shown, the imprint apparatus 100 can include a bridge surface plate that supports the mold operation mechanism 130, a base surface plate that supports the substrate driving unit 160, and the like.

The curing unit 120 cures the imprint material R by irradiating the imprint material R on the substrate W with ultraviolet light via the mold M. The imprint material R can be a UV curing resin. The curing unit 120 can include, for example, a light source unit 121, an optical system 122, and a half mirror 123. The light source unit 121 can include, for example, a light source such as a mercury lamp that generates ultraviolet light (for example, i-line or g-line), and an ellipse mirror that condenses light generated by the light source. The optical system 122 is formed from, for example, a lens, an aperture, and the like that are used to apply the light for curing the imprint material R to the imprint material in the shot region. The light having passed through the optical system is applied to the imprint material R by the half mirror 123. The aperture is used to control the angle of view and control peripheral light shielding. Controlling the angle of view enables illumination of only a target shot region. Controlling peripheral light shielding enables restriction of irradiation of the light beyond the shot region on the substrate. The optical system 122 may include an optical integrator to evenly illuminate the mold M. The light whose range is defined by the aperture strikes the imprint material R on the substrate via the optical system 122 and the mold M. The mold M is, for example, a mold in which a concave-convex pattern such as a circuit pattern or the like of a device has been three-dimensionally formed. The material of the mold M is quartz or the like that can transmit ultraviolet light.

The mold operation mechanism 130 can include, for example, a mold chuck 131 that holds the mold M, a mold driving mechanism 132 that drives the mold M by driving the mold chuck 131, and a mold base 133 that supports the mold driving mechanism 132. The mold driving mechanism 132 can include a positioning mechanism that controls the position of the mold M with respect to six axes, and a mechanism that brings the mold M into contact with the imprint material R on the substrate W and separates the mold M from the cured imprint material R. Here, the six axes are the x, y, z, θx, θy, and θz directions.

The mold shape correction mechanism 140 can be mounted on the mold chuck 131. The mold shape correction mechanism 140 can correct the shape of the mold M by, for example, applying a pressure to the mold from an outer peripheral direction using a cylinder operated by an air fluid or an oil fluid. Alternatively, the mold shape correction mechanism 140 includes a temperature control unit that controls the temperature of the mold M, and can correct the shape of the mold M by controlling the temperature of the mold M. The substrate W can deform (typically, expand or contract) via a process such as annealing. In accordance with the deformation of the substrate W, the mold shape correction mechanism 140 can correct the shape of the mold M such that the overlay error between the pattern of the mold M and the existing pattern on the substrate W falls within an allowable range.

The substrate driving unit 160 can include, for example, a substrate chuck 161, the substrate stage 162, a reference mark table 191, and a stage driving mechanism (not shown). The substrate chuck 161 holds the substrate W. The substrate stage 162 supports the substrate chuck 161, and moves the substrate W by driving the substrate chuck 161. A reference mark 192 is arranged on the reference mark table 191. The stage driving mechanism (not shown) can include a positioning mechanism that controls the position of the substrate W by controlling the position of the substrate stage 162 with respect to the above-described six axes.

The detection apparatus 170 can be used to, for example, detect the relative position (position deviation) between the mold M and the shot region on the substrate W. The detection apparatus 170 can be configured to, for example, illuminate an alignment mark 182 formed on the mold M and an alignment mark 183 formed on the substrate W, and detect the image of the interference fringe (to be also called moire fringe) formed by the light diffracted by the two alignment marks. Based on the detected image, the detection apparatus 170 or the control unit 180 measures the relative position.

The supply unit 190 supplies an imprint material onto the substrate W. The supply unit 190 can include a tank that stores the imprint material, nozzles that discharge, onto the substrate, the imprint material supplied from the tank via a supply path, a valve provided in the supply path, and a supply amount control unit.

The observation scope 193 is a scope for observing the shot region, and includes an image sensor that senses the shot region. The observation scope 193 can be used to check the contact state between the mold M and the imprint material R and the progress of filling of the imprint material R into the concave-convex portion of the pattern of the mold M.

The imprint process performed by the imprint apparatus 100 will be described. The control unit 180 causes a substrate conveyance apparatus (not shown) to convey the substrate W onto the substrate chuck 161, and fix the substrate W on the substrate chuck 161. Then, the control unit 180 moves the substrate stage 162 such that the shot region is located immediately below the mold M.

Then, the control unit 180 drives the mold driving mechanism 132 to bring the mold M into contact with the imprint material R on the substrate W (contact step). When the mold M comes into contact with the imprint material R, the imprint material R flows along the pattern surface of the mold M, and is filled into a space defined by the substrate W and the mold M. In a state in which the mold M and the imprint material R are in contact with each other, the detection apparatus 170 detects the diffracted light from the alignment mark 182 arranged on the mold M and the diffracted light from the alignment mark 183 arranged on the substrate W. Based on the detection results, the control unit 180 performs alignment between the mold M and the substrate W by driving the substrate W, shape correction of the mold M by the correction mechanism, and the like. In this manner, flowing (filling) of the imprint material R with respect to the pattern surface of the mold M, alignment between the mold M and the substrate W, correction of the mold M, and the like are sufficiently performed. Thereafter, the curing unit 120 applies ultraviolet light from the back surface (upper surface) of the mold M, thereby curing the imprint material R by the ultraviolet light transmitted through the mold M (curing step). Subsequently, the control unit 180 drives the mold driving mechanism 132 again to separate the mold M from the cured imprint material R (mold separation step). Thus, the concave-convex pattern of the mold M is transferred to the imprint material R on the substrate W.

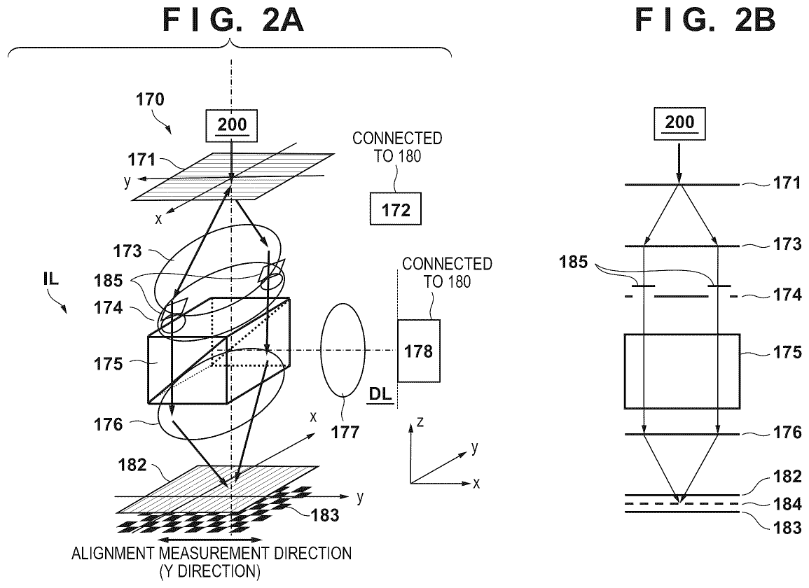

FIG. 2A is a perspective view showing the arrangement of the detection apparatus 170 according to the first embodiment, and FIG. 2B is a y-z sectional view of the detection apparatus 170 shown in FIG. 2A. In FIG. 1, the direction of the light emitted from the detection apparatus 170 is changed by a mirror 179 and the light then illuminates the alignment marks 182 and 183. However, for the sake of illustrative simplicity, the mirror 179 is not shown in FIGS. 2A and 2B.

The detection apparatus 170 includes an illumination optical system IL configured to illuminate the alignment mark 182 (first mark) arranged on the mold M and the alignment mark 183 (second mark) arranged on the substrate W. The illumination optical system IL is configured to perform dipole illumination with light having two poles in its pupil plane. For example, the illumination optical system IL can include a diffraction optical element 171, a lens 173, an aperture stop 174 for implementing dipole illumination, two polarization elements 185, and a beam splitter 175. A detection optical system DL can include a lens 176, the beam splitter 175, a lens 177, and an image sensor 178.

Light from a light source 200 illuminates the diffraction optical element 171. This generates diffracted light beams. The diffracted light beams generated by the diffraction optical element 171 pass through the lens 173, the aperture stop 174, the two polarization elements 185, the beam splitter 175, and the lens 176, and perform dipole illumination on the alignment mark 182 on the mold M and the alignment mark 183 on the substrate W. The two polarization elements 185 are arranged such that the polarization directions of light beams emitted from the two poles, respectively, and striking the substrate are orthogonal to each other. The aperture stop 174 is arranged in or near the pupil plane of the illumination optical system IL. The two polarization elements 185 can be arranged on the side of the light source with respect to the pupil plane.

The alignment marks 182 and 183 are formed by diffraction gratings that have different pitches in the measurement direction. The alignment mark 183 on the substrate W is formed by a checkerboard grating pattern having a y-direction grating pitch and an x-direction grating pitch. The diffracted light beams from the two marks generate an interference fringe (moire fringe) having a light intensity distribution in the y direction as the measurement direction. Here, if the relative position between the mold M and the substrate W fluctuates in the y direction, the phase of the interference fringe changes in accordance with the fluctuation of the relative position. The image of the interference fringe is formed on the light receiving surface of the image sensor 178 by the imaging optical system formed from the lens 176, the beam splitter 175, and the lens 177, and information of the image is transmitted to the control unit 180. Based on the phase information of the interference fringe, the control unit 180 calculates the relative position (deviation amount) between the mold M and the substrate W. Based on the calculation result, the control unit 180 drives the mold driving mechanism 132 and the substrate stage 162, thereby adjusting alignment between the mold M and the substrate W.

In this example, the illumination optical system IL in the detection apparatus 170 is configured to perform dipole illumination by light including two poles in the pupil plane of the illumination optical system IL, and the polarization directions of the light beams emitted from the two poles, respectively, and striking the substrate are orthogonal to each other. Due to the two polarization elements 185, the polarization directions of the two light beams are orthogonal to each other on a substrate surface 184. In this example, the two polarization elements 185 are arranged on the side of the light source with respect to the pupil plane, but the arrangement of the two polarization elements 185 is not limited to this as long as the polarization directions are orthogonal to each other on the substrate surface. For example, the two polarization elements 185 may be arranged on the side of the image plane with respect to the aperture stop 174 configured to implement the dipole illumination. Further, in this example, the optical system illuminates the diffraction optical element, but it is not always necessary to use the diffraction optical element as long as two-beam interference occurs in the optical system. Further, dipole illumination is used in this example, but it is not always necessary to use dipole illumination, and it is also conceivable to use monopole illumination. However, in this case, defocus changes due to a change in apparatus environment such as a change in atmospheric pressure. If defocus changes, the image may be shifted due to the asymmetric illumination and the performance may be degraded.

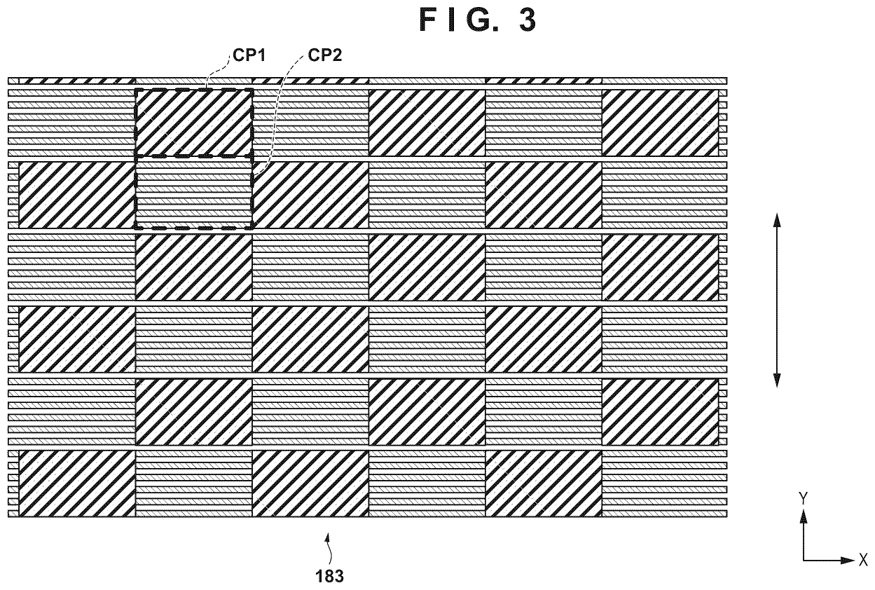

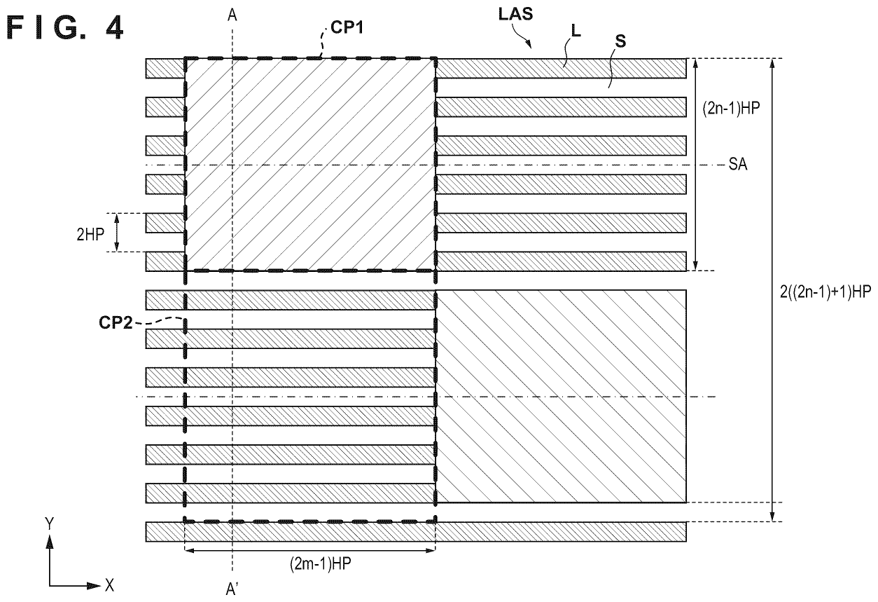

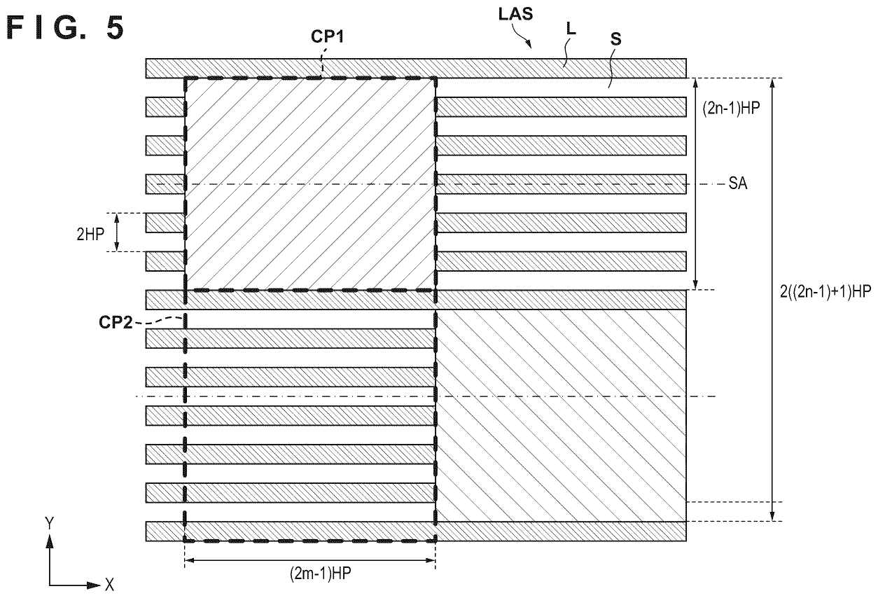

The alignment mark 183 provided on the substrate will be described below. FIG. 3 schematically shows the arrangement of the alignment mark 183 provided on the substrate in the first embodiment. FIGS. 4 and 5 are partially enlarged views of FIG. 3. FIG. 4 shows the first arrangement example, and FIG. 5 shows the second arrangement example. The y direction in FIGS. 3 to 5 is the measurement direction. In this example, the y direction is the first direction and the x direction is the second direction. However, this is merely for the descriptive convenience, and the y direction and the x direction may be interchanged.

In FIGS. 3 to 5, a line-and-space pattern LAS is constituted by a plurality of lines L extending along the x direction, and a plurality of spaces S each sandwiched between the adjacent lines L. The line-and-space pattern LAS can be formed by, for example, a multiple patterning process such as Self Aligned Quadrable Patterning (SAQP). A half pitch HP of the line-and-space pattern LAS can be, for example, 20 nm or less. There is no theoretical limit to the minimum dimension of the half pitch HP of the line-and-space pattern LAS, but the half pitch HP of the line-and-space pattern LAS can be, for example, 1 nm or more.

The alignment mark 183 can be constituted by a plurality of first components CP1 each having a rectangular shape and a plurality of second components CP2 each having a rectangular shape arrayed in a checkerboard pattern. The alignment mark 183 may be understood as an alignment mark structure.

Each first component CP1 can be formed from a flat region. Each second component CP2 can be formed from the line-and-space pattern LAS having the periodicity in the y direction (first direction), and the line-and-space pattern LAS is constituted by the plurality of lines L and the plurality of spaces S arranged alternately. The length of the first component CP1 in the y direction (first direction) can be an odd multiple of the half pitch HP of the line-and-space pattern LAS. In other words, the length of the first component CP1 in the y direction (first direction) can be (2n−1) times the half pitch HP of the line-and-space pattern LAS (n is a natural number), that is, (2n−1) HP. The line-and-space pattern LAS of each second component CP2 is line-symmetric with a straight line as an axis SA passing through the center of the second component CP2 in parallel to the x direction (second direction) orthogonal to the y direction (first direction). According to this arrangement, due to the symmetry of the line-and-space pattern LAS forming the second component CP2 of the alignment mark 183, the detection apparatus 170 can obtain an excellent image. On the other hand, if the line-and-space pattern LAS of the second component CP2 does not have the symmetry about the axis SA, a false signal component can be added to the image of the alignment mark 183 detected by the detection apparatus 170. Therefore, for example, a distortion can occur in the waveform of a measurement signal in the measurement direction obtained from the image, and detection accuracy can be deteriorated.

The length of each of the first component CP1 and the second component CP2 in the x direction (second direction) can be an odd multiple of the half pitch HP. In other words, the length of each of the first component CP1 and the second component CP2 in the x direction (second direction) can be (2m−1) times the half pitch HP (m is a natural number), that is, (2m−1) HP.

In one aspect, it can be understood that the first component CP1 and the second component CP2 adjacent to each other in the y direction (first direction) constitute a unit pattern of the alignment mark 183. The unit pattern forms one period (pitch) in the alignment mark. Note that this period is different from the period of the line-and-space pattern LAS. The length of the unit pattern in the y direction can be 2 ((2n−1)+1) times the half pitch HP of the line-and-space pattern LAS, that is, 4 nHP. The length of the second component CP2 in the y direction (first direction) can be (2n+1) times the half pitch HP of the line-and-space pattern LAS, that is, (2n+1) HP. In the y direction (first direction), the difference between the length of the first component CP1 and the length of the second component CP2 is equal to twice the half pitch HP of the line-and-space pattern LAS.

In the first arrangement example shown in FIG. 4, the second component CP2 includes the space S that contacts the first component CP1 adjacent to the second component CP2 in the positive direction (+y direction) of the y direction (first direction). Further, in the first arrangement example shown in FIG. 4, the second component CP2 includes the space S that contacts the first component CP1 adjacent to the second component CP2 in the negative direction (−y direction) of the y direction.

In the second arrangement example shown in FIG. 5, the second component CP2 includes the line L that contacts the first component CP1 adjacent to the second component CP2 in the positive direction (+y direction) of the y direction (first direction). Further, in the second arrangement example shown in FIG. 5, the second component CP2 includes the line L that contacts the first component CP1 adjacent to the second component CP2 in the negative direction (−y direction) of the y direction.

A specific application example will be described below. Here, assume an alignment mark used for alignment between a substrate and a mold in an imprint apparatus. In addition, assume that a line-and-space pattern with the half pitch HP=20 nm is formed on the substrate by a multiple patterning process. A period (pitch) P1, in the measurement direction, of the alignment mark formed on the mold is expressed by P1=4 nHP=4×25×20 nm=2.0 μm, where n=25. On the other hand, a period (pitch) P2, in the measurement direction, of the alignment mark formed on the substrate is expressed by P2=4 nHP=4×23×20 nm=1.84 μm, where n=23. A period MP of the moire fringe is expressed by:

$$M P = \frac{P 1 \times P 2}{2 \vert P 1 - P 2 \vert} \qquad ( 1 )$$

In this application example, MP=11.5 μm

The second embodiment will be described below. Matters not mentioned concerning the second embodiment can follow the first embodiment. In the second embodiment, an arrangement for performing measurement in both the x direction and the y direction will be exemplarily described.

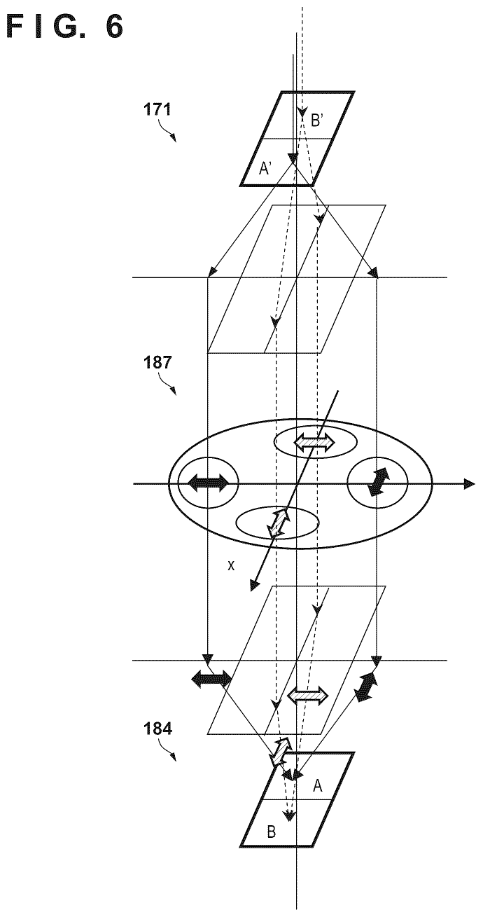

FIG. 6 is a perspective view showing the arrangement of a detection apparatus 170 according to the second embodiment. FIG. 6 schematically shows the arrangement of an alignment mark 183 provided on a substrate in the second embodiment. The detection apparatus 170 is configured to be capable of measuring the relative position between an alignment mark on a substrate and an alignment mark on a mold in both the x direction and the y direction. A pupil plane 187 in FIG. 6 is a simplified illustration of the lens 173, the aperture stop 174, the lens 176, and the polarization elements 185 in FIG. 2A. A diffraction optical element 171 includes a first region A′ that forms illumination light for illuminating a first portion A of a substrate surface 184, and a second region B′ that forms illumination light for illuminating a second portion B of the substrate surface 184 different from the first portion A. The first region A′ of the diffraction optical element 171 diffracts light in the x direction in the surface of the diffraction optical element 171. The light diffracted in the x direction passes through the polarization elements 185 located in the pupil plane 187. The light beams of the polarization direction in the x direction pass through two poles arranged in the x direction, and illuminate the first portion A of the substrate surface 184. By evaluating the interference fringe in the first portion A of the substrate surface 184, it is possible to calculate the relative position deviation amount between a mold M and a substrate W in the y direction.

Similarly, the second region B′ of the diffraction optical element 171 diffracts light in the y direction in the surface of the diffraction optical element 171. The light diffracted in the y direction passes through polarization elements 185 located in the pupil plane 187. The light beams of the polarization direction in the y direction pass through two poles arranged in the y direction, and illuminate the second portion B of the substrate surface 184. By evaluating the interference fringe in the second portion B of the substrate surface 184, it is possible to calculate the relative position deviation amount between the mold M and the substrate W in the x direction.

In this manner, it is possible to simultaneously perform measurement of the position deviation in the x direction (second direction) and measurement of the position deviation in the y direction (first direction).

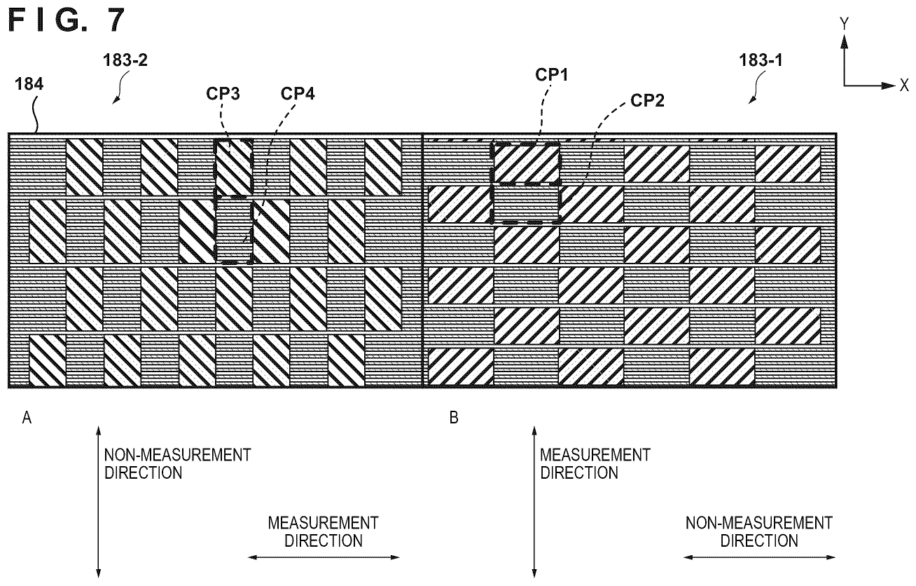

FIG. 7 schematically shows the arrangement of the alignment mark 183 provided on the substrate in the second embodiment. The second portion B of the substrate surface 184 is the first alignment mark corresponding to the alignment mark 183 in the y direction in the first embodiment. The first portion A is the second alignment mark having a structure obtained by rotating the portion of the alignment mark in the second portion B other than the line-and-space pattern by 90°. The measurement direction and the non-measurement direction are different by 90° between the first portion A and the second portion B. The first alignment mark and the second alignment mark form an alignment mark pair.

A first alignment mark 183-1 can be constituted by a plurality of first components CP1 each having a rectangular shape and a plurality of second components CP2 each having a rectangular shape arrayed in a checkerboard pattern. The first alignment mark 183-1 may be understood as the first alignment mark structure.

Each first component CP1 can be formed from a flat region. Each second component CP2 can be formed from the first line-and-space pattern having the periodicity in the y direction (first direction), and the first line-and-space pattern is constituted by a plurality of lines and a plurality of spaces. The length of the first component CP1 in the y direction (first direction) is an odd multiple of a half pitch HP of the first line-and-space pattern. In other words, the length of the first component CP1 in the y direction (first direction) is (2n−1) times the half pitch HP of the first line-and-space pattern (n is a natural number), that is, (2n-1) HP. The line-and-space pattern of each second component CP2 is line-symmetric with a straight line as an axis SA passing through the center of the second component CP2 in parallel to the x direction (second direction) orthogonal to the y direction (first direction).

The length of each of the first component CP1 and the second component CP2 in the x direction (second direction) can be an odd multiple of the half pitch HP of the first line-and-space pattern. In other words, the length of each of the first component CP1 and the second component CP2 in the x direction (second direction) can be (2m−1) times the half pitch HP of the first line-and-space pattern (m is a natural number), that is, (2m−1) HP.

A second alignment mark 183-2 can be constituted by a plurality of third components CP3 each having a rectangular shape and a plurality of fourth components CP4 each having a rectangular shape arrayed in a checkerboard pattern. The second alignment mark 183-2 may be understood as the second alignment mark structure.

Each third component CP3 can be formed from a flat region. Each fourth component CP4 can be formed from the second line-and-space pattern having the periodicity in the y direction (first direction), and the second line-and-space pattern is constituted by a plurality of lines and a plurality of spaces. The length of the third component CP3 in the y direction (first direction) is an odd multiple of the half pitch HP of the second line-and-space pattern. The line-and-space pattern of each fourth component CP4 is line-symmetric with respect to a straight line passing through the center of the fourth component CP4 in parallel to the x direction (second direction).

The half pitch HP of the first line-and-space pattern in the first alignment mark 183-1 in the y direction (first direction) is equal to the half pitch of the second line-and-space pattern in the second alignment mark 183-2 in the y direction.

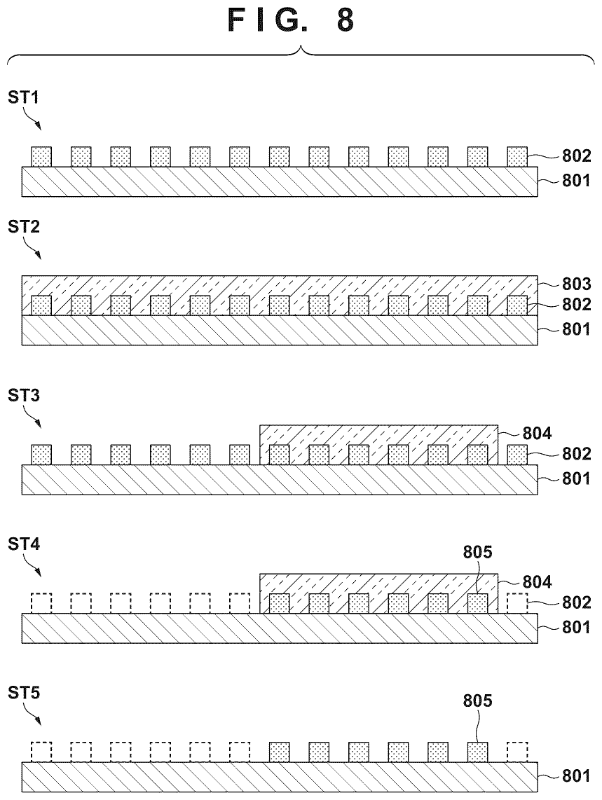

With reference to FIG. 8, a manufacturing method of a semiconductor device including a manufacturing method of the alignment mark according to each of the first and second embodiments will be exemplarily described below. Note that each sectional view shown in FIG. 8 corresponds to a section taken along a line A-A′ in FIG. 4. In step ST1, a line-and-space pattern 802 is formed on a substrate 801. Step ST1 can include a multiple patterning process, for example, Self Aligned Quadrable Patterning (SAQP).

In steps ST2 and ST3, a resist pattern 804 in which a plurality of first components CP1 each having a rectangular shape and a plurality of second components CP2 each having a rectangular shape are arrayed in a checkerboard pattern is formed on the line-and-space pattern 802. First, in step ST2, a photoresist film 803 is applied to cover the substrate 801 and the line-and-space pattern 802. Then, in step ST3, the resist pattern 804 is formed by exposing and developing the photoresist film 803 using a predetermined original and an exposure apparatus.

Then, in step ST4, an alignment mark 805 is formed by etching the line-and-space pattern 802 using the resist pattern 804 as an etching mask. Thereafter, in step ST5, the resist pattern 804 is removed.

Furthermore, by performing a plurality of processes on the substrate obtained through steps ST1 to ST5 described above, a semiconductor device can be formed. The plurality of processes can include, for example, a film formation step, a lithography step, an etching step, a planarization step, a dicing step, a bonding step, a packaging step, and the like. A plurality of processes can be performed before step ST1. The plurality of processes can include, for example, a lithography step, an oxidation step, a film formation step, a silicidation step, a monocrystallization step, a doping step, an etching step, and the like.

While the present invention has been described with reference to exemplary embodiments, it is to be understood that the invention is not limited to the disclosed exemplary. The scope of the following claims is to be accorded the broadest interpretation so as to encompass all such modifications and equivalent structures and functions.

This application claims the benefit of Japanese Patent Application No. 2024-074039, filed Apr. 30, 2024 which is hereby incorporated by reference herein in its entirety.

What is claimed is:

1. An alignment mark in which a plurality of first components each having a rectangular shape and a plurality of second components each having a rectangular shape are arrayed in a checkerboard pattern, wherein
each first component is formed from a flat region,
each second component is formed from a line-and-space pattern having a periodicity in a first direction,
a length of the first component in the first direction is an odd multiple of a half pitch of the line-and-space pattern, and
the line-and-space pattern of each second component is line-symmetric with respect to a straight line passing through a center of the second component in parallel to a second direction orthogonal to the first direction.

2. The mark according to claim 1, wherein
a length of each of the first component and the second component in the second direction is an odd multiple of the half pitch.

3. The mark according to claim 1, wherein
the second component includes a space that contacts the first component adjacent to the second component in a positive direction of the first direction, and a space that contacts the first component adjacent to the second component in a negative direction of the first direction.

4. The mark according to claim 1, wherein
the second component includes a line that contacts the first component adjacent to the second component in a positive direction of the first direction, and a line that contacts the first component adjacent to the second component in a negative direction of the first direction.

5. The mark according to claim 1, wherein
the half pitch is not more than 20 nm.

6. The mark according to claim 1, wherein
in the first direction, a difference between the length of the first component and the length of the second component is equal to twice the half pitch.

7. A substrate comprising an alignment mark defined in claim 1.

8. An alignment mark pair including a first alignment mark used to measure a position in a first direction, and a second alignment mark used to measure a position in a second direction orthogonal to the first direction, wherein
the first alignment mark is an alignment mark in which a plurality of first components each having a rectangular shape and a plurality of second components each having a rectangular shape are arrayed in a checkerboard pattern,
each first component is formed from a flat region,
each second component is formed from a first line-and-space pattern having a periodicity in the first direction,
a length of the first component in the first direction is an odd multiple of a half pitch of the first line-and-space pattern,
the first line-and-space pattern of each second component is line-symmetric with respect to a straight line passing through a center of the second component in parallel to the second direction,
the second alignment mark is an alignment mark in which a plurality of third components each having a rectangular shape and a plurality of fourth components each having a rectangular shape are arrayed in a checkerboard pattern,
each third component is formed from a flat region,
each fourth component is formed from a second line-and-space pattern having a periodicity in the first direction,
a length of the third component in the first direction is an odd multiple of a half pitch of the second line-and-space pattern, and
the second line-and-space pattern of each fourth component is line-symmetric with respect to a straight line passing through a center of the fourth component in parallel to the second direction.

9. The pair according to claim 8, wherein
the half pitch is not more than 20 nm.

10. The pair according to claim 8, wherein
a half pitch of the first line-and-space pattern in the first direction is equal to a half pitch of the second line-and-space pattern in the first direction.

11. A substrate comprising an alignment mark pair defined in claim 8.

12. A manufacturing method of a semiconductor device, comprising:
forming a line-and-space pattern on a substrate;
forming, on the line-and-space pattern, a resist pattern in which a plurality of first components each having a rectangular shape and a plurality of second components each having a rectangular shape are arrayed in a checkerboard pattern; and
forming an alignment mark by etching the line-and-space pattern using the resist pattern as an etching mask.

13. The method according to claim 12, wherein
the forming the line-and-space pattern includes a multiple patterning process.

14. The method according to claim 12, wherein
the forming the line-and-space pattern includes Self Aligned Quadrable Patterning (SAQP).

15. The method according to claim 12, wherein
the line-and-space pattern has a periodicity in a first direction,
each first component is formed from a flat region,
each second component is formed from a part of the line-and-space pattern,
a length of the first component in the first direction is an odd multiple of a half pitch of the line-and-space pattern, and
each second component is line-symmetric with respect to a straight line passing through a center of the second component in parallel to a second direction orthogonal to the first direction.

16. The method according to claim 15, wherein
a length of each of the first component and the second component in a second direction orthogonal to the first direction is an odd multiple of the half pitch.

17. The method according to claim 15, wherein
the second component includes a space that contacts the first component adjacent to the second component in a positive direction of the first direction, and a space that contacts the first component adjacent to the second component in a negative direction of the first direction.

18. The method according to claim 15, wherein
the second component includes a line that contacts the first component adjacent to the second component in a positive direction of the first direction, and a line that contacts the first component adjacent to the second component in a negative direction of the first direction.

19. The method according to claim 15, wherein
the half pitch is not more than 20 nm.

20. The method according to claim 15, wherein
in the first direction, a difference between the length of the first component and the length of the second component is equal to twice the half pitch.
